(19) United States
(12) Patent Application Publication
(10) Pub. No.: US 2008/0225504 A1
(43) Pub. Date: Sep. 18, 2008

(54) Lightweight electromagnetic interference shielding for automotive igniters

(76) Inventors: Virgil A. Chichernea, Mentor, OH (US); Bruce Roberts, Mentor on the Lake, OH (US)

Correspondence Address: FAY SHARPE LLP, 1100 SUPERIOR AVENUE, SEVENTH FLOOR, CLEVELAND, OH, 44114, US

(21) Appl. No.: 11/724,063

(22) Filed: Mar. 14, 2007

(51) Int. Cl. H05K 9/00

(52) U.S. Cl. 361/818

(57) ABSTRACT

In an igniter module housing (F) of an automotive headlamp assembly, an improved EMI shielding includes a thin coating (12) on the housing. This arrangement eliminates the need for separate EMI shielding components. The coating is electrically conductive, typically a metal such as aluminum, and may be sputtered, painted, or dipped onto the plastic substrate at a thickness of approximately 3 microns or less. The total weight of the aluminum coating is on the order of 1 milligram.

### BACKGROUND OF THE INVENTION

This application relates to electromagnetic interference (EMI) shield or shielding, and more particularly, a new lightweight EMI shielding for use with an automotive headlamp assembly. It will be appreciated, however, that the disclosure may find use in related applications.

Automotive headlamp assemblies are known in the art and, more particularly, recent innovations relate to using a discharge lamp in these designs. The discharge lamp requires a stepped-up, high voltage in order to establish an instant-start arc between the electrodes and thereby ionize the fill gas to a discharge state. A transformer assembly is enclosed within a housing associated with the headlamp assembly. The transformer assembly includes a core, and primary and secondary windings to provide the necessary high voltage for operation of the headlamp. For example, U.S. patent application Ser. No. 11/646,213, filed Dec. 26, 2006, entitled “Lamp Igniter Module and Transformer Carrier”; Ser. No. 11/646,009, filed Dec. 27, 2006, entitled “Lamp Transformer”; Ser. No. 11/645,879, filed Dec. 27, 2006, entitled “Lamp Transformer Assembly”; Ser. No. 11/513,777, filed Aug. 31, 2006, entitled “Lamp Transformer; and Ser. No. 11/______, filed Feb. 26, 2007, entitled “High Voltage Transformer and a Novel Arrangement/Method for HID Automotive Headlamps (222270/GECZ 2 00794) are all commonly-assigned to the assignee of the present application and generally relate to this type of automotive headlamp assembly. Further details of the structure and operation of these types of headlamps are provided in these applications, and generally do not form a part of the present disclosure, but are merely cited for background reference.

The headlamp assembly includes an EMI shielding around the transformer assembly to establish a ground plane that encompasses the transformer assembly. The shielding prevents undesired radiation of electromagnetic waves (EMI) into surrounding components. The EMI shield is typically a separate, two-part assembly received around a housing that encloses the transformer assembly. Common materials of construction for the EMI shield are stamped steel or aluminum sheet approximately fifty (50) mils thick that is received over the plastic transformer housing that contains the core and windings. A typical steel EMI shielding weighs approximately twenty-two (22) grams, while an aluminum EMI shielding weighs approximately eight to ten (8-10) grams. The aluminum shielding, for example, is more desirable because of the significant weight reduction relative to steel. Overall weight reduction in an automotive vehicle is always desirable, and when compared to the total lamp ignitor assembly weight of sixty-eight (68) grams, it is evident that a substantial portion of the overall weight of the assembly is contributed by the EMI shield, even when a reduced weight aluminum shielding is used.

As noted, any decrease in weight is desired since this reduces the moment of inertia of the ignitor assembly within the headlamp assembly. Thus, a need exists for weight reduction, and particularly in association with the EMI shielding which contributes fifteen to thirty percent (15-30%) of the overall weight of the ignitor assembly.

### BRIEF DESCRIPTION OF THE INVENTION

An EMI shield includes a thin coating on a structural substrate.

The coating has a thickness on the order of approximately 3 microns, and is electrically conductive.

The electrically conductive coating is preferably a metal, such as aluminum.

The coating weighs approximately 1 milligram and is provided on a majority of an external surface of the housing.

A method of forming the EMI shielding for an automotive headlamp assembly includes providing a substrate or housing. A thin, electrically conductive coating is provided on a surface of the housing.

A conductive coating providing step includes sputtering a metal onto the housing surface.

The sputtering step includes applying metal at a thickness of approximately 3 microns.

Alternatively, the conductive coating step can include painting the coating on the housing surface or dipping the housing in the coating.

The resultant EMI shield is lightweight, has a good finish appearance, has fewer assembly steps, is abrasive-resistant, and reduces the manufacture and assembly costs.

Still other benefits and advantages of the disclosure will become apparent upon reading and understanding the following detailed description.

### BRIEF DESCRIPTION OF THE DRAWINGS

FIG. 1 is an exploded view of a prior art arrangement of a two-part EMI shield received over a ignitor assembly.

FIG. 2 is a perspective view of a headlamp assembly incorporating the new EMI shielding of the present disclosure.

### DETAILED DESCRIPTION OF THE INVENTION

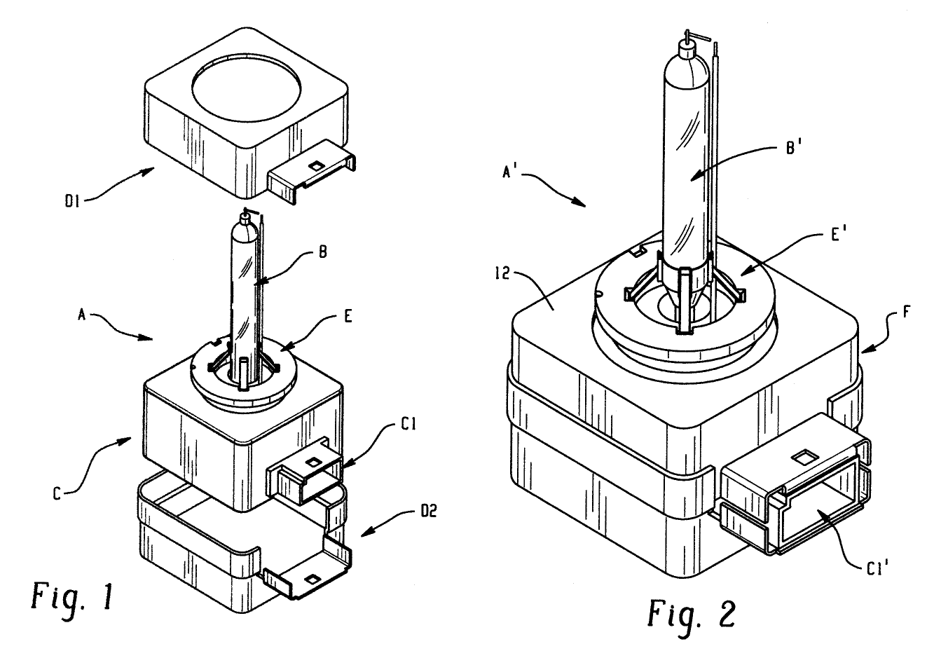

As shown in FIG. 1, a prior art automotive headlamp assembly A is shown and includes a light source such as discharge lamp B extending outwardly from igniter module housing C. A transformer or ignitor assembly (not shown) is enclosed within the housing C and electrical current is provided to the transformer assembly through a receptacle C1 that matingly receives a plug (not shown). Separately received around the housing C is an electromagnetic interference (EMI) shield or shielding which is commonly a two-part assembly D1, D2. The first or upper portion D1 is an inverted, generally cup-shaped arrangement and has a central opening for mounting receipt over the lamp and lamp mounting portion E. The second or lower portion D2 is also generally cup-shaped and closely receives the lower portion of the ignitor housing therein. Each of the first and second portions D1, D2 of the EMI shield are typically a conductive metal, such as stamped steel or aluminum, that mate together to enclose or encompass the ignitor housing. Once assembled together, the shield D1, D2 is electrically and mechanically connected to a grounding strap (not shown) to electrically ground the shield in a manner well known in the art. Thus, in the prior art arrangement, there is a first housing C and a second housing (comprised of two housing portions D1, D2) received over the first housing. This provides an effective EMI ground plate around the high voltage ignitor components of the headlamp assembly. However, the EMI Shield portions D1, D2 contribute significantly to the overall weight of the assembly.

The present disclosure is illustrated in FIG. 2. When assembled as shown in FIG. 2, the headlamp assembly does not look significantly different from the outside from the prior art arrangement. However, this arrangement does not include a separate EMI Shield but only a single housing identified by reference character F in FIG. 2. Thus, where three or more housing portions formed inner housing C (transformer) and outer housing D1, D2 (EMI shielding) in the prior art design of FIG. 1, the arrangement of FIG. 2 includes only one housing portion and in which the EMI shielding is integrated on the external surface thereof.

For purposes of continuity and ease of reference, like components are referred to with a primed suffix, for example, the automotive headlamp assembly A of FIG. 1 bears some resemblance to the new automotive headlamp assembly A′ of FIG. 2. The light source or discharge lamp B′ still extends outwardly from one end of the housing which is now referenced as housing F as shown in FIG. 2. The housing F includes a plastic substrate that has a coating, that is, a conductive coating 12 preferably on external surfaces of the housing portions. The conductive coating is a metallic material such as aluminum because of its light weight. Of course, other conductive materials could also be used if easily applied as a thin coating to the surface of the housing.

The particular dimensions and configuration of the housing can be varied, although the generally cubic shape of the housing is not uncommon. The metallic coating is preferably sputtered on the surface of the plastic substrate. Alternatively, the conductive coating could be painted on to the surface or the plastic substrate can be dipped in the conductive material to form the coating. These latter two alternatives are not as preferable as sputtering since they do not have the good adhesion that is advantageously obtained with the sputtering process. Sputtering a metallic material onto a plastic substrate for cosmetic purposes is generally well-known in the art, and particularly in the automotive component art, so that further details thereof need not be described herein.

The sputtering process is the preferred method of applying the conductive coating to the housing F, and the total thickness of the thin coating can be closely controlled. In the preferred embodiment, the thickness of the aluminum coating is on the order of approximately three microns (3μ). At this thickness, and over the external surface of the housing, the total weight added by the sputtered aluminum is on the order of approximately one milligram (1 mg). As will be appreciated, this is a substantial reduction over the aluminum EMI shielding that weighs approximately eight to ten grams (8-10 g) in the prior art embodiment shown in FIG. 1.

The EMI shielding is still grounded in essentially the same manner. That is, a clip (not shown) establishes electrical contact with the conductive surface of the housing in order to electrically ground the shield.

In summary, an aluminum coating on a plastic housing of an automotive igniter is provided as an EMI shield. The coating on the housing substrate provides the equivalent EMI shielding to the ignitor assembly but at a substantially reduced weight. Rather than using separate steel or aluminum enclosures in addition to the plastic housing as in existing ignitor assemblies, the aluminum coating is preferably sputtered on the plastic housing in a layer a couple of microns thick. The process of the forming the aluminum coating is common in the automotive industry for appearance purposes but has heretofore not been suggested as an EMI shield solution.

This arrangement significantly decreases the weight of an automotive igniter, thereby allowing the design of smaller and higher performance automotive headlamps assembly. Further, fewer assembly steps are required which leads to lower inventory and assembly costs. This embodiment achieves a thickness on the order of approximately 3μ or less at a total weight of approximately 1 milligram or less. The plastic housing serves as a substrate on which the thin electrically conductive coating is provided or applied. As noted, the coating can be either sputtered, painted, or dipped to provide a thin, lightweight conductive coating.

The invention has been described with reference to the preferred embodiments. Obviously, modifications and alterations will occur to others upon reading and understanding the preceding detailed description. It is intended that the invention be construed as including all such modifications and alterations.

What is claimed is:

1. In an igniter module assembly of an associated automotive headlamp having a housing associated therewith, an EMI shield including a thin coating on the housing.

2. The invention of claim 1 wherein the coating has a thickness on the order of approximately three microns.

3. The invention of claim 2 wherein the coating is electrically conductive.

4. The invention of claim 3 wherein the electrically conductive coating is a metal.

5. The invention of claim 4 wherein the electrically conductive metal coating is aluminum.

6. The invention of claim 1 wherein the coating weighs approximately one milligram.

7. The invention of claim 1 wherein the coating is provided on a majority of an external surface of the housing.

8. An electromagnetic interference (EMI) shielding for an associated automotive headlamp assembly that includes a housing that provides power to an associated light source extending from the housing, the EMI shielding comprising:
a thin coating provided on a surface of the housing for limiting radiation of EMI externally of the associated ignitor assembly.

9. The EMI shielding of claim 8 wherein the coating is electrically conductive.

10. The EMI shielding of claim 8 wherein the coating is a metal.

11. The EMI shielding of claim 8 wherein the coating is aluminum at a thickness on the order of approximately three microns.

12. The EMI shielding of claim 8 wherein the coating is aluminum at a total weight of approximately one milligram.

13. A method of forming an electromagnetic interference (EMI) shielding for an associated automotive ignitor assembly for providing desired power to an associated light source, the method comprising:
providing a housing; and
providing a thin electrically conductive coating on a surface of the housing.

14. The method of claim 13 wherein the conductive coating providing step includes sputtering a metal onto the housing surface.

15. The method of claim 14 wherein the sputtering step includes applying the metal at a thickness on the order of approximately three microns.

16. The method of claim 14 wherein the sputtering step includes applying the metal to a weight of approximately one milligram.

17. The method of claim 14 wherein the sputtering step includes applying aluminum to the housing.

18. The method of claim 13 wherein the conductive coating providing step includes painting the coating onto the housing surface.

19. The method of claim 13 wherein the conductive coating providing step includes dipping the housing in the coating.
